(19) United States
(12) Patent Application Publication
(10) Pub. No.: US 2012/0087774 A1
(43) Pub. Date: Apr. 12, 2012

(54) Diced Wafer Adaptor and a Method for Transferring a Diced Wafer

(75) Inventors: Uri Vekstein, Haifa (IL); Itzik Nissany, Herzeliya (IL)

(73) Assignee: CAMTEK LTD, Migdal-Haemek (IL)

(21) Appl. No.: 12/161,698

(22) PCT Filed: Jan. 25, 2007
(86) PCT No.: PCT/IL2007/000102

§ 371 Date: Jul. 4, 2011

Related U.S. Application Data
(60) Provisional application No. 60/762,530, filed on Jan. 27, 2006.

(51) Int. Cl. B23P 17/04; H01L 21/68; B25B 11/00

(52) U.S. Cl. 414/816; 269/21; 29/592

(57) ABSTRACT

A diced wafer adaptor that includes: a cylindrical shaped inner portion, adapted to support and hold an annular frame and a membrane suspended within the annular frame and to apply vacuum to an outer portion of the membrane; wherein an inner portion of the membrane supports a diced wafer and is surrounded by the outer portion of the membrane; and an outer portion having a perimeter shaped substantially as a perimeter of a non-diced wafer.

### FIELD OF THE INVENTION

The invention relates to methods for transferring diced wafers and to a diced wafer adaptor.

### BACKGROUND OF THE INVENTION

Integrated circuits are manufactured by a highly complex process. During the process a wafer that includes multiple dice is placed on a membrane that is suspended within an annular frame. The wafer is diced to provide a diced wafer than includes multiple spaced apart dice. U.S. Pat. No. 6,716,723 of Nepomuceno et al. titled “Wafer cutting using laser marking” and U.S. Pat. No. 6,283,693 of Acello et al. titled “Method and apparatus for semiconductor chip handling”, both being incorporated herein by reference, illustrate prior art wafer dicing methods.

FIG. 1 illustrates a prior art diced wafer (represented by multiple dice 10) that is placed on an inner portion 22 of membrane 20. The inner portion 22 is surrounded by outer portion 24. Membrane (also referred to as tape) 20 is suspended within annular frame 30. Annular frame (also referred to as hoop or ring) 30 usually includes an inner ring and an outer ring. The membrane is placed between these rings and then the rings are connected to each other so as to stretch the membrane and at least partially separate the dice from each other.

During an automatic optical inspection process the diced wafer is manually transferred from one location to the other. The manual transfer process can reduce damages to the diced wafer that is supported by a relatively delicate membrane. Applying uncontrolled pressure on the membrane can cause some of the dice to collide and to be damaged.

This manual process slows the automatic inspection process and complicates (and even prevents) the inspection of diced wafers by the same inspection systems that are adapted to inspect non-diced wafers. Non-diced wafers are relatively rigid and can be transferred by using wafer transferring elements such as but not limited to fork-shaped wafer transferring elements that can apply vacuum to the wafer.

There is a need to provide efficient methods and systems for transferring diced wafers.

### SUMMARY OF THE INVENTION

A diced wafer adaptor that includes: a cylindrical shaped inner portion, adapted to support and hold an annular frame and a membrane suspended within the annular frame and to apply vacuum to an outer portion of the membrane; wherein an inner portion of the membrane supports a diced wafer and is surrounded by the outer portion of the membrane; and an outer portion having a perimeter shaped substantially as a perimeter of a non-diced wafer.

Conveniently, the cylindrical shaped inner portion comprises a very flat inner plate adapted to support the inner portion of the membrane.

Conveniently, the very flat inner plate is made of glass.

Conveniently, the very flat inner plate is placed above at least one projection that defines multiple inner spaces within the diced wafer adaptor.

Conveniently, the cylindrical shaped inner portion includes an annular sidewall that includes a tunnel adapted to receive an elastic element that extends outside the tunnel such as to contact an inner surface of the annular frame.

Conveniently, the cylindrical shaped inner portion includes an elastic element that is adapted to contact an inner surface of the annular frame.

Conveniently, the diced wafer adaptor includes at least one diced wafer alignment marks.

Conveniently, the cylindrical shaped inner portion includes an apertured recess through which vacuum is applied such as to stretch the membrane.

Conveniently, the diced wafer adaptor includes vacuum conduits adapted to receive vacuum from a chuck that supports the diced wafer adaptor and to provide the vacuum to apertures of the apertured recess.

Conveniently, the outer portion optionally other parts of the diced wafer adaptor are made of a rigid material.

A method for transferring a diced wafer is provided. The method includes: placing a membrane suspended within an annular frame on a diced wafer adaptor that includes a cylindrical shaped inner portion and an outer portion having a perimeter shaped substantially as a perimeter of a non-diced wafer; wherein the cylindrical shaped inner portion is adapted to support and hold the annular frame and the membrane that supports the diced wafer; placing the diced wafer adaptor on a chuck by using a wafer transferring element; and applying, by the diced wafer adaptor, vacuum to an outer portion of the membrane such as to stretch the membrane within the annular frame.

Conveniently, the method includes placing the diced wafer adaptor on an alignment table and aligning the diced wafer to the diced wafer adaptor.

Conveniently, the method includes placing an inner portion of the membrane on a very flat inner plate that belongs to the cylindrical shaped inner portion.

Conveniently, the method includes placing an inner portion of the membrane on a very flat inner plate that is made of glass.

Conveniently, the method includes pressing the annular frame against an elastic element connected to the cylindrical shaped inner portion.

Conveniently, the method includes aligning the diced wafer in response to at least one alignment mark of the diced wafer adaptor.

Conveniently, the method includes conveying vacuum from the chuck and via vacuum conduits of the diced wafer adaptor.

### BRIEF DESCRIPTION OF THE DRAWINGS

The present invention will be understood and appreciated more fully from the following detailed description taken in conjunction with the drawings in which:

FIG. 1 illustrates a prior art membrane suspended within an annular frame and supporting a diced wafer;

FIG. 2 illustrates a diced wafer adaptor according to an embodiment of the invention;

FIG. 3 is a cross sectional view of the diced wafer adaptor according to an embodiment of the invention;

FIG. 4 illustrates a diced wafer adaptor, a membrane and an annular frame according to an embodiment of the invention;

FIG. 5 illustrates a wafer transferring element, a diced wafer adaptor, a membrane and an annular frame according to an embodiment of the invention;

FIG. 6 is a cross sectional view of a wafer transferring element, a diced wafer adaptor, a membrane and an annular frame according to an embodiment of the invention;

FIG. 7 illustrates a diced wafer adaptor that is positioned on a chuck, according to an embodiment of the invention;

FIG. 8 illustrates an alignment table according to an embodiment of the invention;

FIG. 9 illustrates an alignment table and a diced wafer adaptor according to an embodiment of the invention;

FIG. 10 illustrates a method for transferring a diced wafer, according to an embodiment of the invention;

FIG. 11 illustrates a diced wafer adaptor according to a further embodiment of the invention; and

FIG. 12 is another cross sectional view of the diced wafer adaptor according to yet a further embodiment of the invention.

### DETAILED DESCRIPTION OF THE DRAWINGS

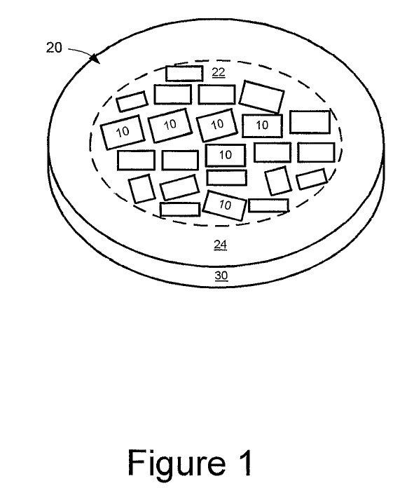

It is noted that the various drawings, and especially FIGS. 1,4,5,6, and 7 are out of scale. In addition some drawings do not include all the features of the diced wafer adaptor (such as notch 114), for simplicity of explanation.

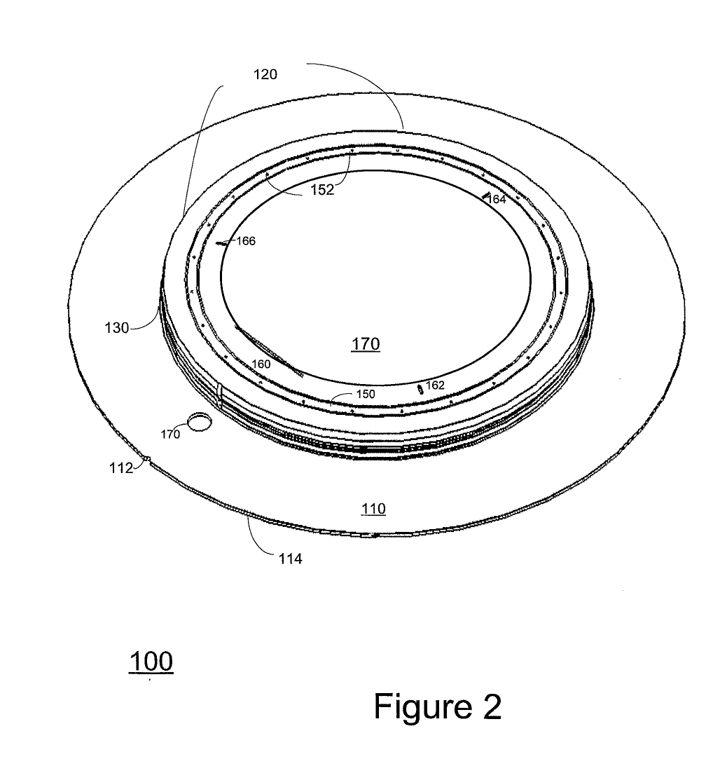

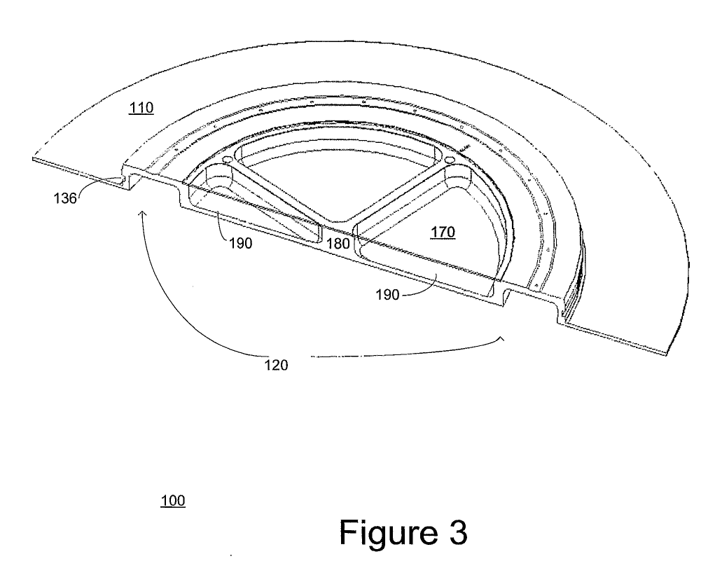

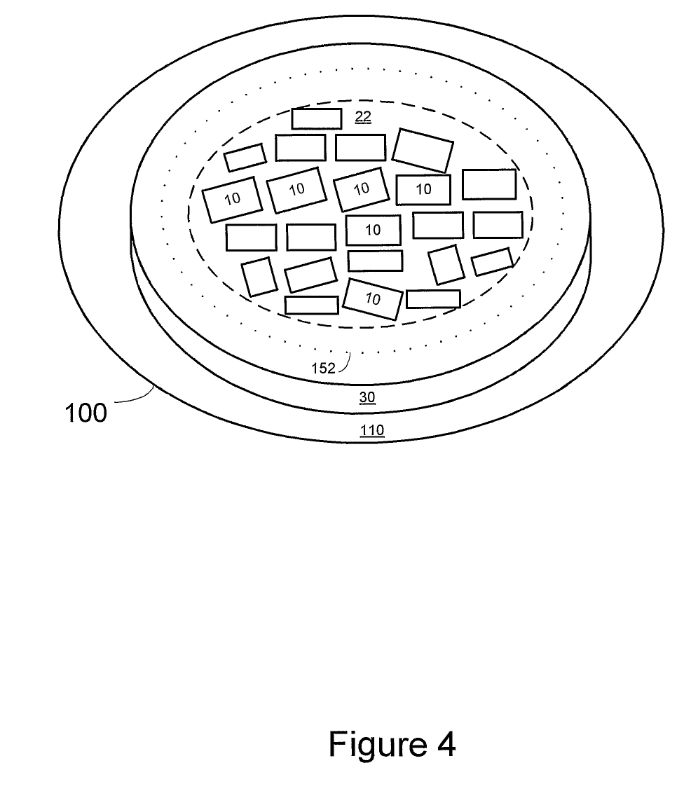

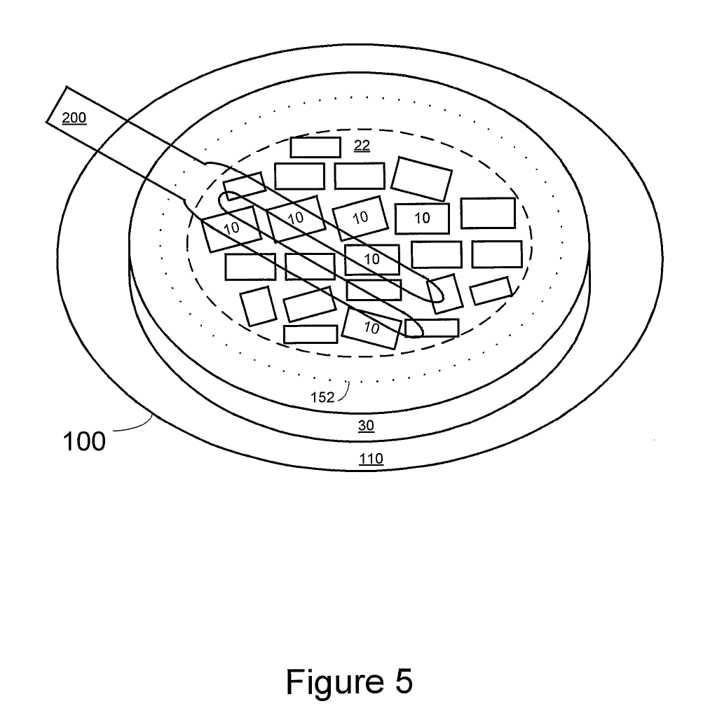

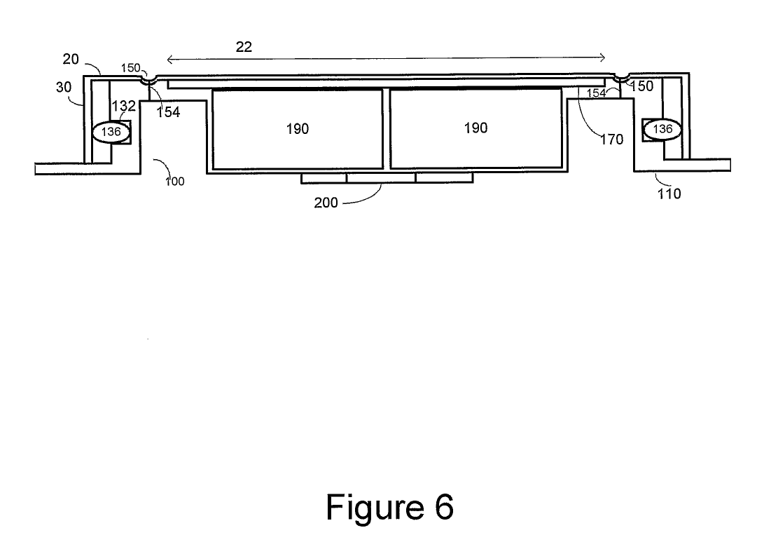

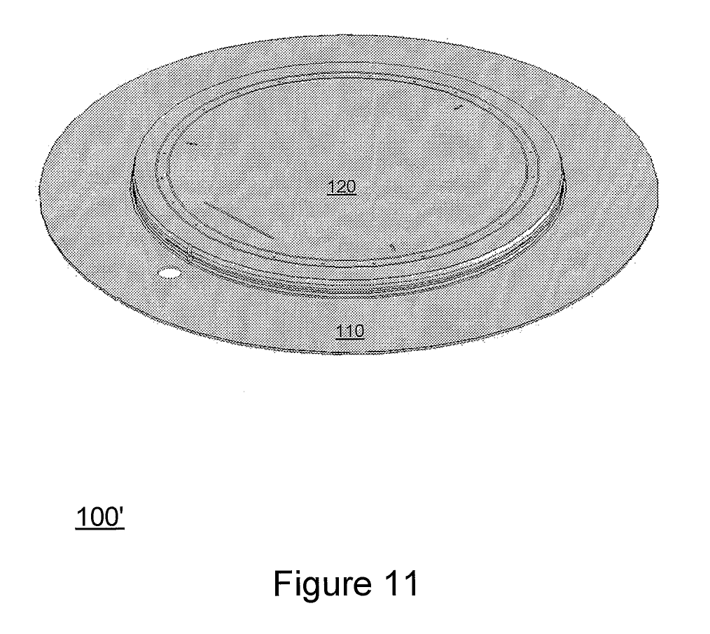

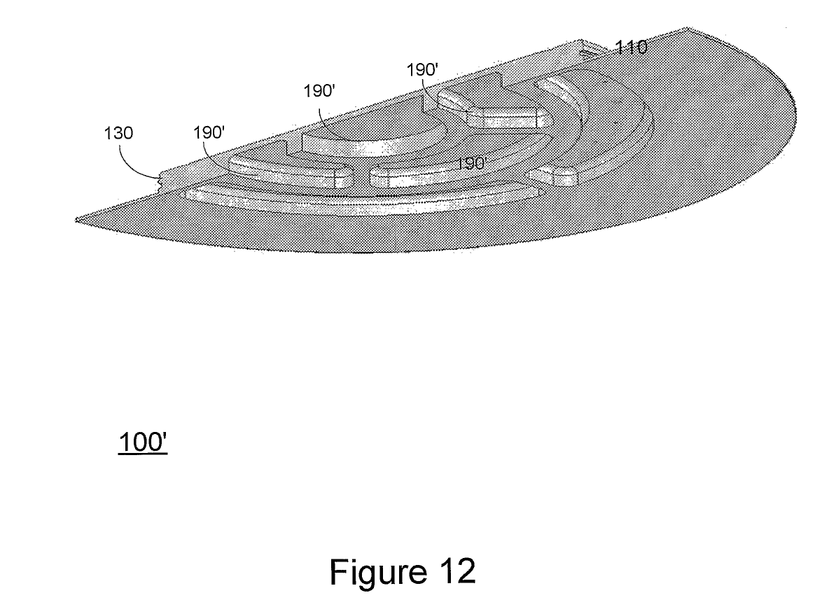

FIG. 2 illustrates diced wafer adaptor 100 according to an embodiment of the invention, FIG. 3 is a cross sectional view of diced wafer adaptor 100 according to an embodiment of the invention, FIG. 4 illustrates diced wafer adaptor 100, membrane 20 and annular frame 30 according to an embodiment of the invention, FIG. 5 illustrates wafer transferring element 200, diced wafer adaptor 100, membrane 20 and annular frame 30 according to an embodiment of the invention, FIG. 6 is a cross sectional view of wafer transferring element 200, diced wafer adaptor 100, membrane 20 and annular frame 30 according to an embodiment of the invention, FIG. 11 illustrates diced wafer adaptor 100′ according to a further embodiment of the invention, and FIG. 12 is another cross sectional view of diced wafer adaptor 100′according to yet a further embodiment of the invention.

Diced wafer adaptor 100′ of FIGS. 11 and 12 differs from diced wafer adaptor 100 by having inner spaces 190′ that face downwards (instead of facing upwards as inner spaces 190 of diced wafer adaptor 100) and by having an cylindrical shaped inner portion 120 that is made of a single material. For simplicity of explanation the following description will refer to diced wafer adaptor 100.

Diced wafer adaptors 100 includes a cylindrical shaped inner portion 120 and an outer portion 110. Cylindrical shaped inner portion 120 is adapted to support and hold annular frame 30 and membrane 20 and to apply vacuum (via apertures 152) to outer portion 24 of membrane 20. Conveniently, cylindrical shaped inner portion 120 is shaped such as to fill (or at least substantially fill) a cylindrical space defined by the lower surface of membrane 20 and the inner surface of annular frame 30.

Outer portion 110 of diced wafer adaptor 100 has a perimeter 114 that is shaped substantially as a perimeter of a non-diced wafer. It can be circular, almost circular and can include an alignment recess such as alignment recess 112. The alignment recess (also referred to as notch) 112 enables an inspection system, and especially a pre-aligner within the inspection system to align the diced wafer adaptor 100 to an imaginary axis that is conveniently parallel to some (or most) of dice 10.

The shape of perimeter 144 can slightly differ from the shape of a non-diced wafer as long that the diced wafer adapter can be transferred by wafer transferring element 200 and can be aligned by aligned by the inspection tool and especially by a pre-aligner within the inspection system.

Conveniently, cylindrical shaped inner portion 120 includes a very flat inner plate 170 that is adapted to support inner portion 22 of membrane 20. Conveniently, very flat inner plate 170 is made of glass.

Conveniently, very flat inner plate 170 is placed above at least one projection 180 that defines multiple inner spaces 190 within diced wafer adaptor 100. Inner spaces 190 are formed in order to reduce the weight of diced wafer adaptor 100.

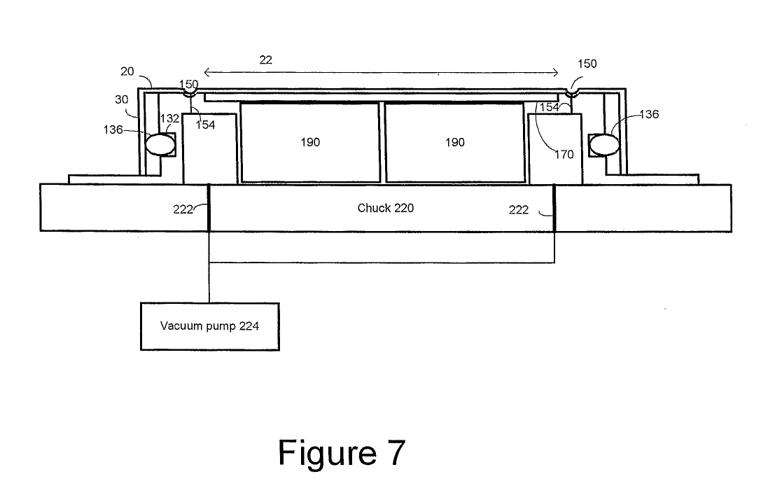

Cylindrical shaped inner portion 120 can include an annular sidewall 130 that includes tunnel 132 that is adapted to receive elastic element 136. Elastic element 136 extends outside tunnel 132 such as to contact an inner surface of annular frame 120. Elastic element 136 provides a firm support to annular rings 30 of various sizes. Thus, even if the diameter of cylindrical shaped inner portion 120 is slightly smaller than the diameter of annular frame 130 the elastic element 136 can bridge the gap and firmly hold annular frame 30. FIGS. 6 and especially FIG. 7 illustrate an exemplary spatial relationship between diced wafer adaptor 100 and annular frame 130. In FIG. 6 the gap between diced wafer adaptor 100 and annular frame 130 is bridged by elastic element 136.

It is noted that elastic element 136 can be connected to cylindrical shaped inner portion 120 in various manners known in the art and that the connection by tunnel 132 is optional. It is noted that elastic element 136 can be of various shapes, and that multiple elastic elements can be used.

According to an embodiment of the invention diced wafer adaptor 100 includes one or more diced wafer alignment marks such as but not limited to alignment line 160 and three alignment marks 162-166 that are positioned around very flat inner plate 170 at about one hundred and twenty degrees from each other. The diced wafer alignment marks can be seen even when annular frame 130 and membrane 20 are placed on diced wafer adaptor 100. Thus, the annular frame 130 can be rotated about its axis until the diced wafer is substantially aligned with the alignment marks.

The alignment can include rotating annular frame 130 until multiple dice 10 are substantially parallel to line 160.

Conveniently, cylindrical shaped inner portion 120 includes two annular shaped upper surfaces 140 and 142 and an apertured recess 150 that is defined between these two annular shaped upper surfaces.

Apertured recess 150 is positioned such as to contact the outer portion 24 of membrane 20.

Vacuum can be applied through apertures 152 of apertured recess 150 such as to further stretch membrane 20. The stretching affect is achieved by sucking membrane 20 towards apertures 152.

Conveniently, diced wafer adaptor 100 includes vacuum conduit 154 that is adapted to receive vacuum from a chuck (such as chuck 220 of FIG. 7) that supports the diced wafer adaptor 100 and to provide the vacuum to apertures 152 of apertured recess 150.

It is noted that the vacuum can be applied by multiple recesses, by non-annular shaped recesses, and the like. Thus, for example, instead of having a single ring-shaped recess 150 multiple non-consecutive recesses can be provided. Yet for another example, multiple co-axial recesses can be provides.

Conveniently, outer portion 110 is made of a rigid material such as aluminum. This rigid material enables to transfer the diced wafer adaptor 100 by automatic transfer means such as but not limited to wafer transferring element 200 of FIGS. 6-7. Wafer transfer element 200 can apply vacuum on the rigid outer portion 110 without affecting the diced wafer.

FIG. 7 illustrates diced wafer adaptor 100 that is positioned on chuck 220, according to an embodiment of the invention. FIG. 7 illustrates a vacuum path that starts at vacuum pump 224, extends via vacuum conduit 222 within chuck 220, and ends at apertures 152 of diced wafer adaptor 100.

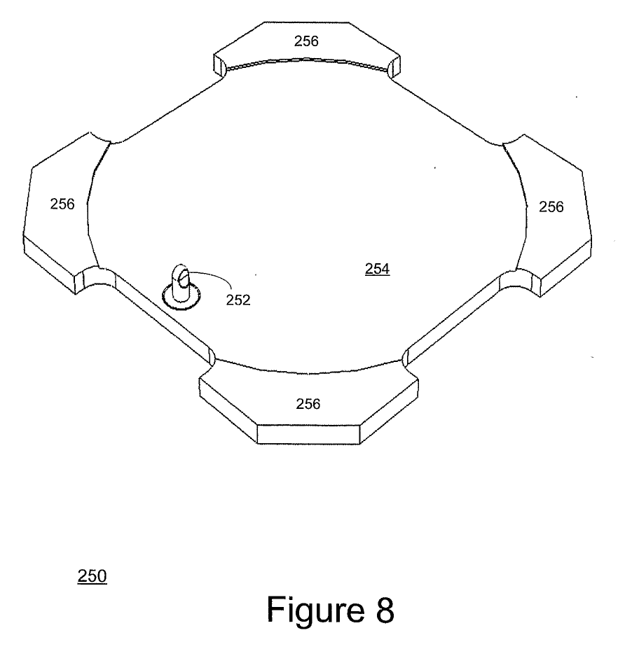

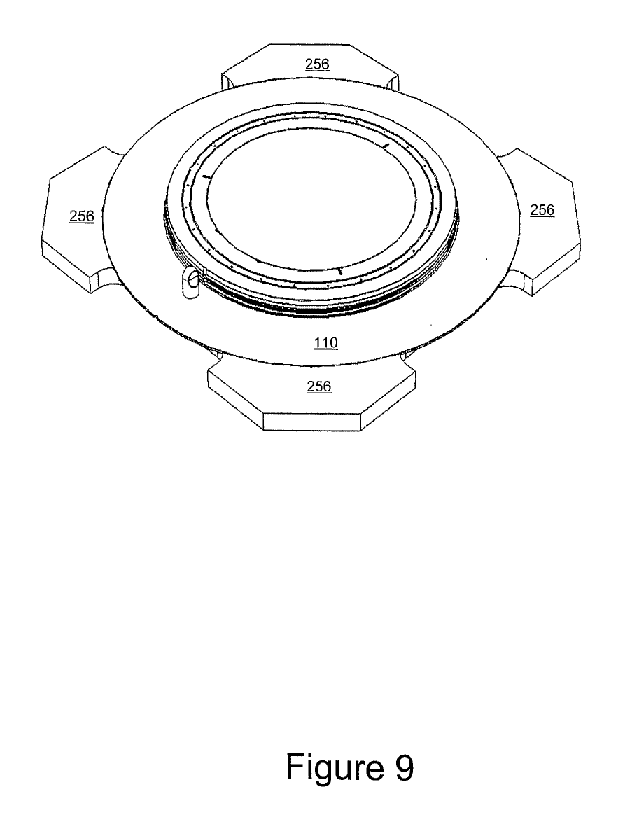

FIG. 8 illustrates alignment table 250 according to an embodiment of the invention. FIG. 9 illustrates alignment table 250 and diced wafer adaptor 100 according to an embodiment of the invention.

Alignment table 250 includes a vertically extending pin 252 as well as a flat circular shaper surface 254 that is partially surrounded by slightly elevated limiters 256.

The diced wafer adaptor 100 includes an aperture 170 (formed at its outer portion 110) through which the vertically extending pin 252 can extend.

Accordingly, aperture 170 and pin 252 define the spatial relationship between alignment table 250 and diced wafer adaptor 100.

Once diced wafer adaptor 100 is placed on alignment target 180 the annular ring 130 can be rotated such as to align the diced wafer to the diced wafer adaptor 100 that in turn is aligned to alignment target 180.

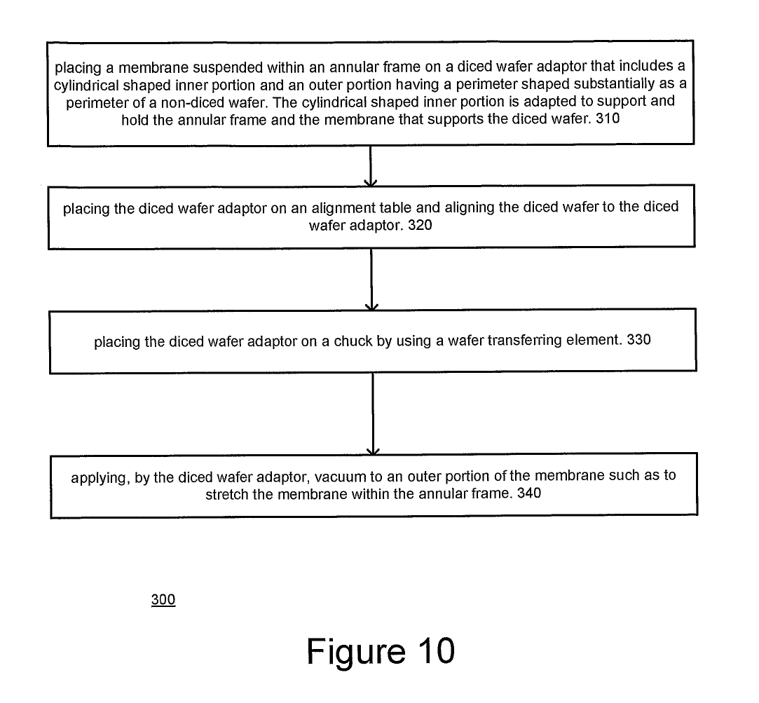

FIG. 10 illustrates method 300 for transferring a diced wafer, according to an embodiment of the invention.

Method 300 starts by stage 310 of placing a membrane suspended within an annular frame on a diced wafer adaptor that includes a cylindrical shaped inner portion and an outer portion having a perimeter shaped substantially as a perimeter of a non-diced wafer. The cylindrical shaped inner portion is adapted to support and hold the annular frame and the membrane that supports the diced wafer.

Conveniently, stage 310 includes placing an inner portion of the membrane on a very flat inner plate that belongs to the cylindrical shaped inner portion. Conveniently, stage 310 includes placing an inner portion of the membrane on a very flat inner plate that is made of glass.

Conveniently, stage 310 includes pressing the annular frame against an elastic element connected to the cylindrical shaped inner portion.

Stage 310 is followed by optional stage 320 of placing the diced wafer adaptor on an alignment table and aligning the diced wafer to the diced wafer adaptor.

Conveniently, stage 320 can be replaced by another optional stage of aligning the diced wafer in response to at least one alignment mark of the diced wafer adaptor.

Stage 320 is followed by stage 330 of placing the diced wafer adaptor on a chuck by using a wafer transferring element.

Stage 330 may include placing a diced wafer adaptor on a chuck by using a wafer transferring element. The membrane is suspended within an annular frame and is placed on the diced wafer adaptor. The diced wafer adaptor includes a cylindrical shaped inner portion and an outer portion having a perimeter shaped substantially as a perimeter of a non-diced wafer. The cylindrical shaped inner portion is adapted to support and hold the annular frame and the membrane that supports the diced wafer. Stage 330 is followed by stage 340 of applying, by the diced wafer adaptor, vacuum to an outer portion of the membrane such as to stretch the membrane within the annular frame. Conveniently, stage 340 includes conveying vacuum from the chuck and via vacuum conduits of the diced wafer adaptor.

Stage 340 can be followed by inspecting the diced wafer and then removing the diced wafer, using the wafer transferring element.

Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

We claim:

1. A diced wafer adaptor comprising:
a cylindrical shaped inner portion, adapted to support and hold an annular frame and a membrane suspended within the annular frame and to apply vacuum to an outer portion of the membrane; wherein an inner portion of the membrane supports a diced wafer and is surrounded by the outer portion of the membrane; and
an outer portion having a perimeter shaped substantially as a perimeter of a non-diced wafer.

2. The diced wafer adaptor according to claim 1 wherein the cylindrical shaped inner portion comprises a very flat inner plate adapted to support the inner portion of the membrane.

3. The diced wafer adaptor according to claim 2 wherein the very flat inner plate is made of glass.

4. The diced wafer adaptor according to claim 2 wherein the very flat inner plate is placed above at least one projection that defines multiple inner spaces within the diced wafer adaptor.

5. The diced wafer adaptor according to claim 1 wherein the cylindrical shaped inner portion comprises an annular sidewall that comprises a tunnel adapted to receive an elastic element that extends outside the tunnel such as to contact an inner surface of the annular frame.

6. The diced wafer adaptor according to claim 1 wherein the cylindrical shaped inner portion comprises an elastic element that is adapted to contact an inner surface of the annular frame.

7. The diced wafer adaptor according to claim 1 further comprising diced wafer alignment marks.

8. The diced wafer adaptor according to claim 1 wherein the cylindrical shaped inner portion comprises defines an apertured recess through which vacuum is applied such as to stretch the membrane.

9. The diced wafer adaptor according to claim 8 comprising vacuum conduits adapted to receive vacuum from a chuck that supports the diced wafer adaptor and to provide the vacuum to apertures of the apertured recess.

10. The diced wafer adaptor according to claim 1 wherein the outer portion is made of a rigid material.

11. The diced wafer adaptor according to claim 10 wherein the cylindrical shaped inner portion is made of the rigid material from which the outer portion of the diced wafer adaptor is made of.

12. A method for transferring a diced wafer, the method comprising:
placing a diced wafer adaptor on a chuck by using a wafer transferring element; wherein a membrane suspended within an annular frame is placed on the diced wafer adaptor; wherein the diced wafer adaptor comprises a cylindrical shaped inner portion and an outer portion having a perimeter shaped substantially as a perimeter of a non-diced wafer; wherein the cylindrical shaped inner portion is adapted to support and hold the annular frame and the membrane that supports the diced wafer; and
applying, by the diced wafer adaptor, vacuum to an outer portion of the membrane such as to stretch the membrane within the annular frame.

13. The method according to claim 12 further comprising placing the membrane suspended within an annular frame on the diced wafer adaptor

14. The method according to claim 13 further comprising placing the diced wafer adaptor on an alignment table, placing the annular frame on the diced wafer adaptor and aligning the diced wafer to the diced wafer adaptor.

15. The method according to claim 13 wherein the stage of placing the membrane comprises placing an inner portion of the membrane on a very flat inner plate that belongs to the cylindrical shaped inner portion.

16. The method according to claim 13 wherein the stage of placing the membrane comprises placing an inner portion of the membrane on a very flat inner plate that is made of glass.

17. The method according to claim 13 wherein the stage of placing the membrane comprises pressing the annular frame against an elastic element connected to the cylindrical shaped inner portion.

18. The method according to claim 13 further comprising aligning the diced wafer in response to at least one alignment mark of the diced wafer adaptor.

19. The method according to claim 13 wherein the stage of applying comprises conveying vacuum from the chuck and via vacuum conduits of the diced wafer adaptor.

20. The method according to claim 13 wherein the stage of placing the membrane comprises placing an inner portion of the membrane on the cylindrical shaped inner portion that is made of a rigid material from which the outer portion of the diced wafer adaptor is made of.
